(19) United States
(12) Patent Application Publication
(10) Pub. No.: US 2001/0022380 A1
(43) Pub. Date: Sep. 20, 2001

(54) Integrated MOS transistor with a high threshold voltage and low multiplication coefficient

(76) Inventors: Matteo Patelmo, Trezzo Sull'Adda (IT); Giovanna Dalla Libera, Monza (IT); Bruno Vajana, Bergamo (IT)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/737,842

(22) Filed: Dec. 14, 2000

(30) Foreign Application Priority Data
Dec. 17, 1999 (IT) TO99A 001112

(51) Int. Cl. H01L 29/76; H01L 29/94; H01L 31/062; H01L 31/113; H01L 31/119

(52) U.S. Cl. 257/402

(57) ABSTRACT

A transistor of the integrated MOS type with a high threshold voltage and low multiplication coefficient is formed in a chip that includes a substrate and defining an active area delimited by field oxide regions. The active area partially houses a tub having the same type of conductivity as the substrate and a greater doping level. In particular, the tub occupies a first half of the active area, while a second half of the active area is formed directly by the substrate. A gate region is present above the substrate and is isolated from the substrate by means of a gate oxide layer. The gate region is arranged partially above the second half of the active area and partially above the tub. The transistor also comprises a source region, which is formed in the tub on a first side of the gate region, and a drain region, which is arranged in the second half of the active area, on a second side of the gate region. Therefore, the transistor has a channel region which is delimited between the source region and drain region and one half of which has a first doping level and the other half a second doping level greater than the first doping level; consequently, the transistor has a high threshold voltage.

### TECHNICAL FIELD

The present invention relates to a MOS transistor with a high threshold voltage and low multiplication coefficient.

### BACKGROUND OF THE INVENTION

Many integrated devices currently present on the market use high and low voltage transistors (also referred to below as HV and LV transistors, respectively) both of the NMOS and PMOS type, dual gate type (i.e., having the gate region doped with doping ion species of the same type as the source and drain regions) and drain extension type. In these devices, in order for the channel lengths of the transistors to be less than 0.5 μm, it is necessary to raise the doping level of the substrate in a suitable manner so as to avoid undesirable effects such as, for example, “punch-through”, i.e., the undesirable electrical connection of two regions with different potential. For this reason, the region intended to house these transistors is enriched with doping ions designed to impart the same type of conductivity as the substrate, forming a tub having a doping level greater than that of the said substrate.

In many devices, however, it is also indispensable to have transistors with a low multiplication coefficient (i.e., with a low ratio of current flowing in the drain region and current flowing in the substrate) which requires a low doping level of the substrate.

A solution to this problem, which is commonly adopted, is that of providing, by means of a suitable design of the masks, so-called “no-tub” transistors formed directly in the substrate, instead of in a tub.

Since these transistors have a low multiplication effect, but also a low threshold voltage, they may be used only with suitable circuit arrangements in order to prevent unacceptable parasitic currents.

An arrangement is illustrated in FIGS. 1 and 2, where a no-tub transistor with a low threshold voltage and low multiplication coefficient is connected in series to a tub transistor with a high threshold voltage and high multiplication coefficient.

In particular, a first MOS transistor 1 with a high multiplication coefficient and high threshold and a second transistor 2 with a low multiplication coefficient and low threshold are formed in a chip 3 of semiconductor material and are surrounded by field oxide regions 9 which delimit a first active area 5, where the first MOS transistor 1 is formed, and a second active area 6, where the second transistor 2 is formed.

The chip 3 is formed by a substrate 4 of monocrystalline silicon, here of the P-type, housing, in the first active area 5, a tub 7 (indicated by means of the positively hatched area in FIG. 2) enriched with doping ion species designed to impart the same type of conductivity as the substrate 4, but a greater doping level. On the other hand, the second active area 6 does not comprise any tub.

Each transistor 1, 2 comprises a gate region 10a and 10b, respectively, arranged above the substrate 4 and isolated from the latter by a gate oxide layer 11. Each transistor 1, 2 also comprises a source region 5a and 5b, respectively, and a drain region 6a and 6b, respectively; the source and drain regions 5a, 6a of the first transistor 1 are formed in the tub 7; the source and drain regions 5b, 6b of the second transistor 2 are formed directly in the substrate 4. The source and drain regions 5a, 5b, 6a and 6b, which are of the N type, are indicated by means of the negatively hatched area in FIG. 2 and are arranged on opposite sides of the gate regions 10a, 10b.

Respective enriched regions 18a, 19a, 18b and 19b, of the N⁺ type, are present within the source and drain regions 5a, 5b, 6a and 6b.

A dielectric protective layer 14 extends above the substrate 4 and is interrupted only at the location of openings containing contact regions 15-18, which are made of metallic material and extend as far as the enriched regions 18a, 19a, 18b and 19b. The transistors 1, 2 are interconnected by means of a metallic layer 20 extending above the dielectric protective layer 14. In particular, the drain region 6a of the first transistor 1 is connected to the source region 5b of the second transistor 2. The transistors 1, 2 are therefore connected in series.

Since the source and drain regions 5a, 6a of the first transistor 1 are formed in the tub 7, with a high doping level, the first transistor 1 has a high threshold voltage and high multiplication coefficient. Vice versa, since the source and drain regions 5b, 6b of the second transistor 2 are formed directly in the substrate 4, which is less doped than the tub 7, the second transistor 2 has a low multiplication coefficient and low threshold.

In this way, the assembly formed by the series connection of the transistors 1 and 2 provides simultaneously a high threshold voltage and low multiplication coefficient.

This arrangement, however, has the disadvantage of large spatial dimensions since the formation of an additional transistor is required.

### SUMMARY OF THE INVENTION

The disclosed embodiments of the present invention, therefore, provide a MOS transistor able to overcome the above-mentioned drawbacks.

In accordance with the disclosed embodiments of the present invention, an integrated MOS transistor is provided that includes a substrate of semiconductor material of a first conductivity type and a first doping level; a gate region arranged above and isolated from the substrate; a first conductive region and a second conductive region with a second conductivity type formed in the substrate on first and second sides, respectively, of the first gate region and delimiting a channel region between them; and a channel region comprising a first portion with a first doping level and a second portion with a second doping level greater than the first doping level.

In accordance with another aspect of the invention, the first portion is formed by the substrate and a second portion is formed in a tub arranged in the substrate. In one embodiment, the tub surrounds the first conductive region, which can be the source region.

In accordance with another aspect of the present invention, the second portion is formed in a tub that is entirely underneath the gate region. Ideally, the tub is located a distance from the first conductive region and from the second conductive region wherein the first portion is formed by the substrate and comprises a first zone extending between the tub and the first conductive region and a second zone extending between the tub and the second conductive region.

### BRIEF DESCRIPTION OF THE DRAWINGS

So that the present invention may be understood, two preferred embodiments thereof are now described, purely by way of a non-limiting example, with reference to the accompanying drawings in which:

FIG. 1 shows a cross-section through a chip incorporating a pair of known transistors;

FIG. 2 shows a plan view of the chip according to FIG. 1;

FIG. 3 shows a cross-section through a chip of semiconductor material housing a first embodiment of the transistor according to the invention;

FIG. 4 shows a plan view of the chip according to FIG. 3;

FIG. 5 shows a cross-section through a chip of semiconductor material housing a further embodiment of the transistor according to the invention; and

FIG. 6 shows a plan view of the chip according to FIG. 5.

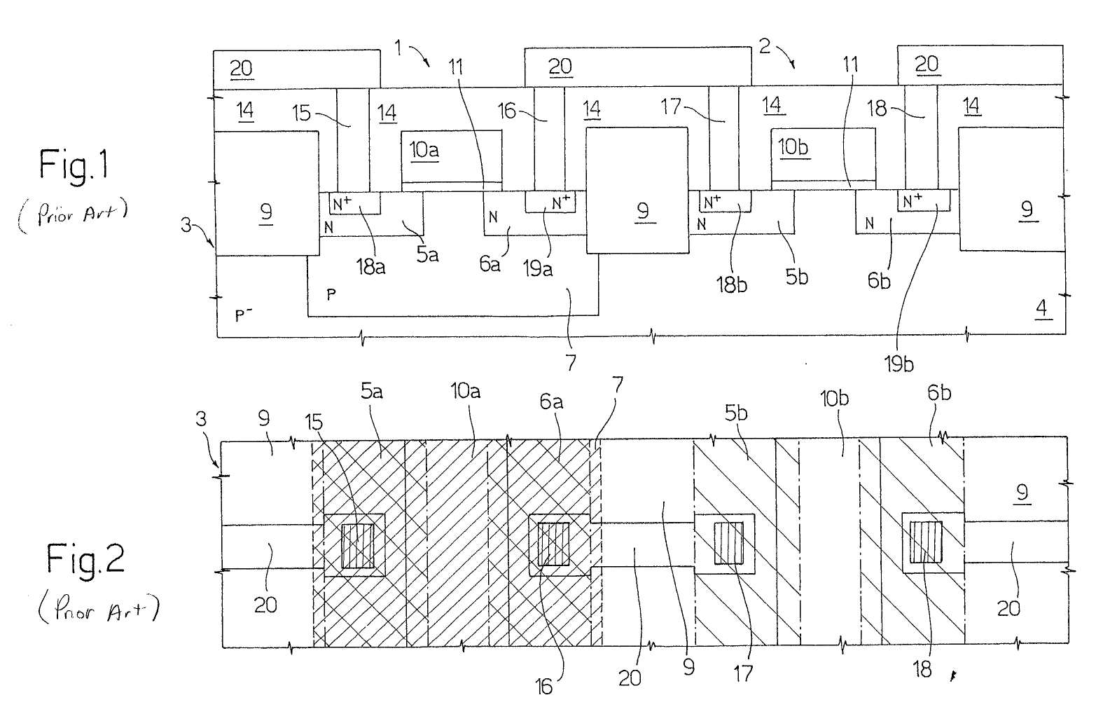

### DETAILED DESCRIPTION OF THE INVENTION

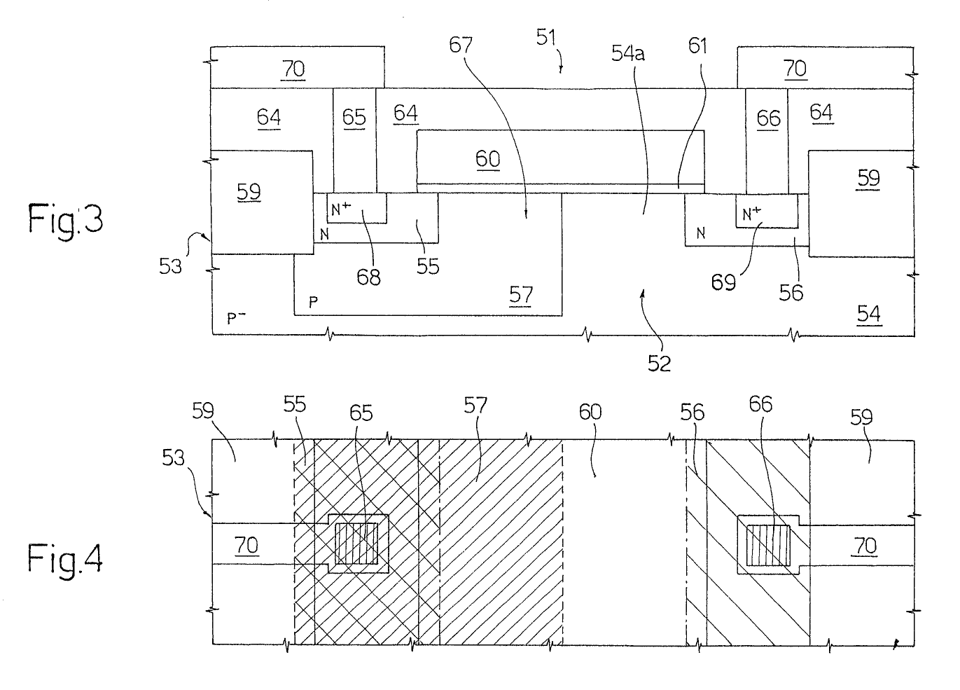

FIGS. 3 and 4 show a chip 50 of semiconductor material incorporating a transistor 51 of the integrated MOS type. The chip 50 comprises a P⁻ type substrate 54 having a doping level of 1*10¹⁶ and defining an active area 52 delimited by field oxide regions 59.

The active area 52 partially houses a tub 57 having the same type of conductivity as the substrate 54, and therefore of the P type, and a greater doping level, for example 1*10¹⁷. In particular, as can be clearly seen in FIG. 4, where it is shown in the form of a positively hatched area, the tub 57 occupies a first half of the active area 52, i.e., the left-hand half, while a second half of the active area 52, indicated by 54a in FIG. 3, is formed directly by the substrate 54.

A gate region 60, which is isolated from the substrate 54 by means of a gate oxide layer 61, is present above the substrate 54.

The gate region 60 is arranged partially above the second half 54a of the active area 52 and partially above the tub 57.

The tub 57 is formed using a P-well mask, not shown, which covers only the second half 54a of the active area 52 and by implanting P-type doping ion species in the substrate 54.

The transistor 51 also comprises an N-type source region 55, which is formed in the tub 57 on a first side of the gate region 60, and an N-type drain region 56, which is arranged in the second half 54a of the active area 52, on a second side of the gate region 60.

Therefore, the transistor 51 has a channel region 67 which is delimited between the source region 55 and the drain region 56 and one half of which has a first doping level (in the second half 54a of the active area 52) and the other half a second doping level greater than the first doping level (in the tub 57); consequently, the transistor 51 has a high threshold voltage.

Respective enriched regions 68, 69 of the N⁺ type are present inside the source and drain regions 55, 56.

A dielectric protective layer 64 extends above the substrate 54 and is interrupted only at the location of the contacts. In particular, as shown in the FIG. 3, the dielectric protective layer 64 has openings containing contact regions 65 and 66 which are made of metallic material and extend as far as the enriched regions 68, 69 and are connected to metallic interconnecting regions 70 for electrical connection to other components of the integrated circuit (not shown).

The solution described has the following advantages.

Firstly, since the gate region 60 is formed partially above the tub 57 with a high doping level, the transistor 51 has a high threshold voltage; at the same time, since the drain region 56 is formed directly in the substrate 54, where the tub 57 is not present and, since the substrate 54 has a low doping level, the transistor 51 has a low multiplication coefficient.

In this way, it is possible to avoid the complex circuit arrangements which were necessary previously and, in particular, it is possible to eliminate a transistor; therefore, smaller spatial dimensions are obtained.

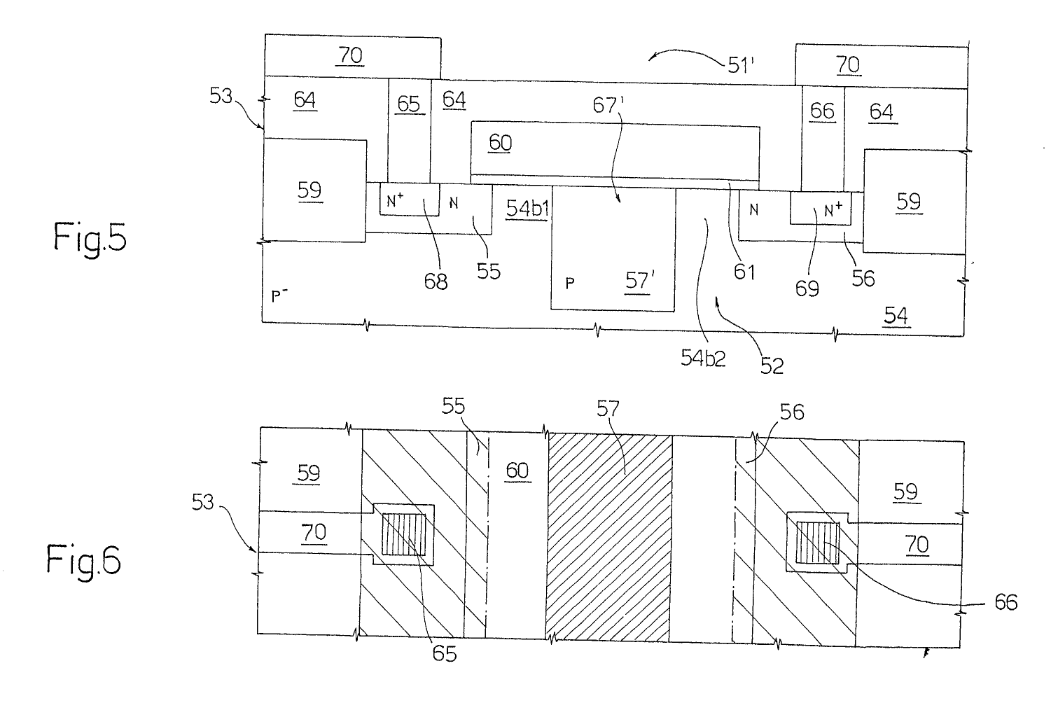

FIGS. 5 and 6 show a transistor 51′ which is similar to the transistor 51 shown in FIGS. 3 and 4, except with regard to the position of the enriched tub. Consequently, identical parts are indicated by the same numbers.

The transistor 51′ has a P-type tub 57′ arranged entirely underneath the gate region 60 and located at a distance from the source region 55 and drain region 56. In the example shown, the tub 57′ is arranged exactly in the center of the channel region, indicated here by 67′, and the second active area half is divided into two parts, each arranged on a different side of the tub 57′ and indicated here by 54b1 and 54b2.

The transistor 51′ has a low multiplication coefficient and high threshold voltage. In fact, the transistor 51′ has a high threshold voltage as a result of the tub 57′ which has a greater doping level than that of the substrate 54 and a low multiplication coefficient owing to the fact that the source region 55 and drain region 56 are formed directly in the substrate 54 which is less doped.

Finally, it is obvious that the integrated MOS transistor described and illustrated here may be subject to numerous modifications and variations, all of which fall within the scope of the invention, as defined in the accompanying claims and the equivalents thereof.

For example, it is possible to provide both HV and LV transistors of the NMOS or PMOS type.

1. An integrated MOS transistor comprising a substrate made of semiconductor material with a first type of conductivity and a first doping level; a gate region arranged above and isolated from said substrate; a first conductive region and a second conductive region with a second type of conductivity, which are formed in said substrate respectively on a first and on a second side of said first gate region and delimiting a channel region between them; said channel region comprising a first portion with a first doping level and a second portion with a second doping level greater than the first doping level.

2. The integrated MOS transistor of claim 1, wherein said first portion is formed by said substrate and said second portion is formed by a tub arranged in said substrate.

3. The integrated MOS transistor of claim 2, wherein said tub surrounds said first conductive region.

4. The integrated MOS transistor of claim 3, wherein said first conductive region is a source region.

5. The integrated MOS transistor of claim 2, wherein said tub is entirely formed underneath said gate region.

6. The integrated MOS transistor of claim 5, wherein said tub is located at a distance from said first conductive region and from said second conductive region and wherein said first portion is formed by said substrate and comprises a first zone extending between said tub and said first conductive region and a second zone extending between said tub and said second conductive region.

7. The integrated MOS transistor of claim 6, wherein said tub is arranged in the center of said channel region.

8. The integrated MOS transistor of claim 1, further comprising contact regions made of metallic material and extending from said first conductive region and said second conductive region.

9. The MOS transistor of claim 8, wherein said first and second conductive regions have a third doping level and surround enriched regions with said second type of conductivity and fourth doping level, greater than said third doping level.

10. An integrated MOS transistor comprising:
a substrate of semiconductor material having a source region and a drain region formed therein, and a gate region formed on the substrate to define a channel region in the substrate between the source and drain regions;
an active area formed in the substrate at least below the gate region and having a first conductivity type with a first doping level; and
a tub formed in the active area below the gate region and having the same conductivity type as the active area with a second doping level that is different than the first doping level, the channel region comprising a first channel portion having the first doping level of the active area and a second channel portion having the second doping level of the tub.

11. The transistor of claim 10, wherein the second doping level comprises a higher doping level than the first doping level.

12. The transistor of claim 10, wherein the source region is formed in the tub.

13. The transistor of claim 10, wherein the tub is sized and shaped to form a first zone of active area between the tub and the source region and a second zone of active area between the tub and the drain region.

14. The transistor of claim 13, wherein the tub is formed below the center of the gate region.

15. A transistor of the integrated MOS type having a high threshold voltage and a low multiplication coefficient, comprising:
a substrate defining an active area delimited by field oxide regions, the active area partially housing a tub having a conductivity type that is the same as a conductivity type of the substrate and having a greater doping level than the active area, the tub occupying a first half of the active area and a second half of the active area being formed directly by the substrate; and
a gate region formed above the substrate and isolated from the substrate by means of a gate oxide layer, the gate region arranged partially above the second half of the active area and partially above the tub.

16. The transistor of claim 15, comprising a source region formed in the tub on a first side of the gate region and a drain region that is formed in the second half of the active area on a second side of the gate region.

17. The transistor of claim 16, comprising a channel region delimited between the source region and the drain region, one-half of which has a first doping level and the other half of which has a second doping level greater than the first doping level.
